(19) United States
(12) Patent Application Publication
(10) Pub. No.: US 2012/0119225 A1
(43) Pub. Date: May 17, 2012

(54) SILICON CARBIDE SUBSTRATE, EPITAXIAL LAYER PROVIDED SUBSTRATE, SEMICONDUCTOR DEVICE, AND METHOD FOR MANUFACTURING SILICON CARBIDE SUBSTRATE

(75) Inventors: Hiromu Shiomi, Osaka-shi (JP); Hideto Tamaso, Osaka-shi (JP); Shin Harada, Osaka-shi (JP); Takashi Tsuno, Osaka-shi (JP); Yasuo Namikawa, Osaka-shi (JP)

(73) Assignee: SUMITOMO ELECTRIC INDUSTRIES, LTD., Osaka-shi (JP)

(21) Appl. No.: 13/322,089

(22) PCT Filed: Feb. 21, 2011
(86) PCT No.: PCT/JP2011/053720

§ 371 Date: Nov. 22, 2011

(30) Foreign Application Priority Data
Jun. 9, 2010 (JP) 2010-132253

(51) Int. Cl. H01L 29/24; H01L 21/20

(52) U.S. Cl. 257/77; 438/478; 257/E29.104; 257/E21.09

(57) ABSTRACT

The present invention provides a silicon carbide substrate, an epitaxial layer provided substrate, a semiconductor device, and a method for manufacturing the silicon carbide substrate, each of which achieves reduced on-resistance. The silicon carbide substrate is a silicon carbide substrate having a main surface, and includes: a SiC single-crystal substrate formed in at least a portion of the main surface; and a base member disposed to surround the SiC single-crystal substrate. The base member includes a boundary region and a base region. The boundary region is adjacent to the SiC single-crystal substrate in a direction along the main surface, and has a crystal grain boundary therein. The base region is adjacent to the SiC single-crystal substrate in a direction perpendicular to the main surface, and has an impurity concentration higher than that of the SiC single-crystal substrate.

### TECHNICAL FIELD

The present invention relates to a silicon carbide substrate, an epitaxial layer provided substrate, a semiconductor device, and a method for manufacturing the silicon carbide substrate, more particularly, a silicon carbide substrate, an epitaxial layer provided substrate, a semiconductor device, and a method for manufacturing the silicon carbide substrate, each of which achieves reduced on-resistance.

### BACKGROUND ART

Conventionally, semiconductor devices each employing a silicon carbide (SiC) substrate have been proposed (for example, see Japanese Patent Laying-Open No. 2007-141950 (Patent Literature 1) and U.S. Pat. No. 6,803,243 (Patent Literature 2)). For example, in Japanese Patent Laying-Open No. 2007-141950, in a vertical type semiconductor device, an ohmic electrode of non-heat treatment type is formed on the backside surface of the silicon carbide substrate. Meanwhile, U.S. Pat. No. 6,803,243 discloses an art in which ions are implanted into a surface of the silicon carbide substrate, then activation annealing is performed, and then an ohmic electrode is formed on the ion-implanted surface of the silicon carbide substrate. The documents described above achieve a low-resistant ohmic contact in the silicon carbide substrate, which results in reduced on-resistance of the semiconductor device.

### CITATION LIST

### Patent Literature

PLT 1: Japanese Patent Laying-Open No. 2007-141950

PLT 2: U.S. Pat. No. 6,803,243

### SUMMARY OF INVENTION

### Technical Problem

However, each of the conventional semiconductor devices described above has the following problem. That is, in each of the conventional semiconductor devices described above, the on-resistance is reduced as a result of reducing the contact resistance for the ohmic electrode formed on the silicon carbide substrate, but there is no particular measure taken to reduce the resistance of the silicon carbide substrate itself. This makes it difficult to sufficiently reduce the on-resistance in the semiconductor device (in particular, vertical type semiconductor device). Although it is considered to grind such a silicon carbide substrate having a relatively large electric resistance for removal thereof, the backside surface of the silicon carbide substrate needs to be grinded while protecting the front-side surface thereof in this case. This results in a complicated process. Further, when forming an ohmic electrode on a surface of the silicon carbide substrate thus grinded, there is a restriction as to a temperature for heat treatment or the like because the device has been already formed. This makes it difficult to form the ohmic electrode, disadvantageously.

The present invention is made to solve the above-described problems, and an object of the present invention is to provide a silicon carbide substrate, an epitaxial layer provided substrate, a semiconductor device, and a silicon carbide substrate, each of which achieves reduced on-resistance.

### Solution to Problem

A silicon carbide substrate according to the present invention is a silicon carbide substrate having a main surface, and includes: a single-crystal member formed in at least a portion of the main surface; and a base member disposed to surround the single-crystal member. The base member includes a boundary region and a base region. The boundary region is adjacent to the single-crystal member in a direction along the main surface and has a crystal grain boundary therein. The base region is adjacent to the single-crystal member in a direction perpendicular to the main surface and has an impurity concentration higher than that of the single-crystal member.

In this way, because the single-crystal member is disposed in the main surface of the silicon carbide substrate, an epitaxial layer made of silicon carbide of good film-quality can be readily formed on the main surface. On the other hand, when forming a vertical type semiconductor device using the silicon carbide substrate, the silicon carbide substrate needs to have a large conductivity in order to reduce the on-resistance of the vertical type semiconductor device. Hence, by disposing the base region having an impurity concentration higher than that in the single-crystal member, the conductivity of the silicon carbide substrate in its thickness direction (vertical direction) can become large (i.e., electric resistance value can be reduced). Hence, the on-resistance of the semiconductor device employing the silicon carbide substrate can be reduced in the vertical direction.

Further, a high-quality epitaxial film is basically to be formed on the main surface of the silicon carbide substrate. Hence, the single-crystal member having a small defect density (excellent crystallinity) is used. On the other hand, only a portion (boundary region) of the base member is exposed in the main surface. Hence, the base member may be adapted to have a lower level of defect density or the like to be satisfied, than that in the single-crystal member. Hence, as the base member, there can be used a material doped with a conductive impurity at a high concentration (having an increased conductivity), without being limited by generation of defects. Further, such a base member can be used as a reinforcement member for maintaining mechanical strength of the silicon carbide substrate. Further, an ohmic electrode can be readily formed on the base member having the high impurity concentration.

Further, because required level for crystallinity in the base member is not high as described above, a material (silicon carbide material) of low quality (inferior in crystallinity) can be used as the base member. Accordingly, a manufacturing cost for the silicon carbide substrate can be reduced as compared with a case where the entire silicon carbide substrate is constituted by a high-quality material such as the single-crystal member.

An epitaxial layer provided substrate according to the present invention includes: the silicon carbide substrate; and an epitaxial layer formed on the main surface of the silicon carbide substrate and made of silicon carbide. Further, the epitaxial layer preferably has an impurity concentration lower than that of the single-crystal member. In this case, a high-quality semiconductor device can be manufactured readily using the epitaxial layer that thus utilizes silicon carbide having high crystallinity (small in defect).

A semiconductor device according to the present invention is configured using the silicon carbide substrate. In this case, for example, when forming a vertical type semiconductor device, conductivity of the silicon carbide substrate in its thickness direction can be sufficiently secured, thereby attaining a semiconductor device with reduced on-resistance.

In a method for manufacturing a silicon carbide substrate according to the present invention, first, the step of preparing a single-crystal member made of silicon carbide and having a main face is performed. Performed thereafter is the step of forming a base member made of silicon carbide having an impurity concentration higher than that of the single-crystal member so as to cover the main face and an end face of the single-crystal member, the end face being connected to the main face and extending in a direction crossing the main face. Performed next is the step of flattening at least a surface of the single-crystal member by partially removing the single-crystal member and the base member from a side opposite to the main face of the single-crystal member.

In this way, the silicon carbide substrate according to the present invention can be manufactured readily. Further, for the base member, a material (silicon carbide) having a lower crystallinity (for example, higher defect density) than that of the single-crystal member can be used. Hence, the silicon carbide substrate can be manufactured at a lower cost than that in the case where the entire silicon carbide substrate is constituted by high-quality silicon carbide such as the single-crystal member.

### Advantageous Effects of Invention

Thus, the present invention can provide a silicon carbide substrate, an epitaxial layer provided substrate, a semiconductor device, and a method for manufacturing the silicon carbide substrate, each of which achieves reduced on-resistance.

### BRIEF DESCRIPTION OF DRAWINGS

FIG. 1 is a cross sectional view schematically showing a silicon carbide substrate according to the present invention.

FIG. 2 is a flowchart for illustrating a method for manufacturing the silicon carbide substrate shown in FIG. 1.

FIG. 3 is a schematic view for illustrating the flowchart of FIG. 2.

FIG. 4 is a schematic view for illustrating the flowchart of FIG. 2.

FIG. 5 is a schematic view for illustrating the flowchart of FIG. 2.

FIG. 6 is a schematic view for illustrating the flowchart of FIG. 2.

FIG. 7 is a schematic view for illustrating the flowchart of FIG. 2.

FIG. 8 is a schematic view for illustrating the flowchart of FIG. 2.

FIG. 9 is a cross sectional view schematically showing an exemplary semiconductor device that employs the silicon carbide substrate shown in FIG. 1.

FIG. 10 is a schematic view for illustrating a method for manufacturing the semiconductor device shown in FIG. 9.

FIG. 11 is a schematic view for illustrating a method for manufacturing the semiconductor device shown in FIG. 9.

FIG. 12 is a schematic view for illustrating a method for manufacturing the semiconductor device shown in FIG. 9.

FIG. 13 is a cross sectional view schematically showing another exemplary semiconductor device that employs the silicon carbide substrate in the present invention.

FIG. 14 is a cross sectional view schematically showing a variation of the first embodiment of the silicon carbide substrate shown in FIG. 1 in the present invention.

FIG. 15 is a schematic view for illustrating a method for manufacturing the silicon carbide substrate shown in FIG. 14.

FIG. 16 is a schematic view for illustrating a method for manufacturing the silicon carbide substrate shown in FIG. 14.

FIG. 17 is a cross sectional view schematically showing a silicon carbide substrate of a second embodiment in the present invention.

FIG. 18 is a cross sectional view schematically showing an epitaxial layer provided substrate according to the present invention.

FIG. 19 is a cross sectional view schematically showing a variation of the epitaxial layer provided substrate shown in FIG. 18.

FIG. 20 is a cross sectional view schematically showing a variation of the epitaxial layer provided substrate shown in FIG. 18.

FIG. 21 is a cross sectional view schematically showing a silicon carbide substrate of a fourth embodiment in the present invention.

FIG. 22 is a graph showing a result of measurement for a relation between a drain voltage and a drain current in an example of the semiconductor device of the present invention.

### DESCRIPTION OF EMBODIMENTS

The following describes embodiments of the present invention with reference to figures. It should be noted that in the below-mentioned figures, the same or corresponding portions are given the same reference characters and are not described repeatedly.

### First Embodiment

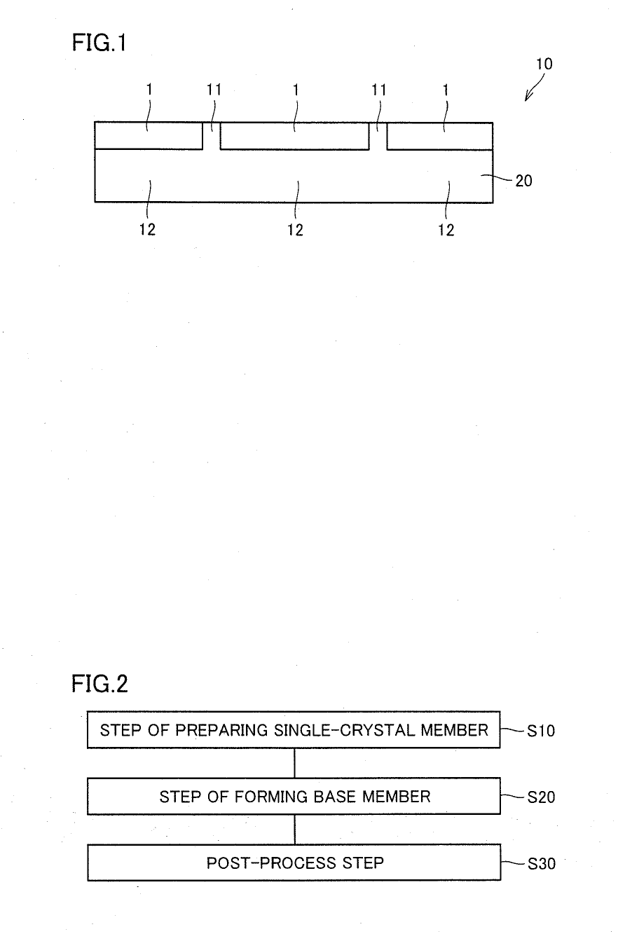

Referring to FIG. 1, a silicon carbide substrate of a first embodiment according to the present invention will be described.

As shown in FIG. 1, a silicon carbide substrate 10 according to the present invention is a composite substrate including SiC single-crystal substrates 1 each serving as a single-crystal member, and a base member 20 serving as a supporting base. Silicon carbide substrate 10, which has a circular planar shape, has one main surface in which the plurality of SiC single-crystal substrates 1 are arranged to be exposed as shown in FIG. 1. These SiC single-crystal substrates 1 are arranged with spaces between one another. Each of the SiC single-crystal substrates has a main face corresponding to the (0-33-8) plane, for example. Base member 20, which is made of SiC, is disposed to fill the spaces between SiC single-crystal substrates 1 and to cover the lower surface of each of SiC single-crystal substrates 1. From a different point of view, it can be said that in one main surface of base member 20, the plurality of SiC single-crystal substrates are disposed with spaces therebetween (are embedded such that portions of their surfaces are exposed). Each of portions of base member 20 between SiC single-crystal substrates 1 is a boundary region 11, which is a polycrystal region having a crystal grain boundary therein. Further, a portion of base member 20 below SiC single-crystal substrates 1 is a base region 12, which is formed of a single-crystal. Base region 12 has an impurity concentration higher than that of each of SiC single-crystal substrates 1. It should be noted that boundary region 11 can have a width (width in a direction along the main surface of silicon carbide substrate 10) not less than 1 μm, more preferably, not less than 10 μm and not more than 1000 μm. Such a numerical range is determined for the following reason. That is, this boundary region 11 serves to suppress propagation of defects, and therefore needs to have a width of 1 μm or greater, which is sufficiently large in view of the sizes of dislocations which may be propagated. On the other hand, boundary region 11 is a portion from which no device property is obtained. Hence, it is desirable that boundary region 11 has a width of 1000 μm or smaller.

In this way, SiC single-crystal substrates 1 are disposed in the main surface of silicon carbide substrate 10, whereby an epitaxial layer made of silicon carbide having a good film-quality can be readily formed on the main surface thereof. Further, the impurity concentration of base region 12 is relatively high, which allows for large conductivity (reduced electric resistance value) in the thickness direction (vertical direction) of silicon carbide substrate 10. Accordingly, the on-resistance can be reduced in the vertical direction in a semiconductor device employing this silicon carbide substrate 10.

Further, as base member 20 and boundary region 11, silicon carbide having a lower crystallinity (higher dislocation density) than that in each SiC single-crystal substrate 1 can be employed. Hence, silicon carbide substrate 10 can be manufactured at low cost. Furthermore, base member 20 and boundary region 11 can be utilized as a reinforcement member for maintaining the mechanical strength of silicon carbide substrate 10, and therefore provides an effect of reducing warpage. Further, an ohmic electrode can be readily formed on base member 20 having the high impurity concentration.

Further, because the plurality of SiC single-crystal substrates 1 are disposed in the front-side surface of base member 20 with the spaces therebetween, dislocations propagating in SiC single-crystal substrates 1 are absorbed in boundary regions 11. This suppresses the dislocations from propagating throughout silicon carbide substrate 10.

Further, in silicon carbide substrate 10, the impurity concentration of each of boundary regions 11 may be higher than that of each of SiC single-crystal substrates 1. In this case, dislocations propagating in each of SiC single-crystal substrates 1 (for example, basal plane dislocations) can be absorbed more effectively by boundary region 11. This suppresses warpage of silicon carbide substrate 10, which would have been caused by dislocations propagating throughout silicon carbide substrate 10.

Referring to FIG. 2-FIG. 8, a method for manufacturing the silicon carbide substrate shown in FIG. 1 will be described.

As shown in FIG. 2, first, a step (S10) of preparing the single-crystal members is performed. Specifically, there are prepared the plurality of SiC single-crystal substrates 1 (see FIG. 1), each of which is a single-crystal member serving as a tile substrate. The main faces of these SiC single-crystal substrates 1 preferably have the same crystal orientation. Further, each main face of the planar shape of SiC single-crystal substrates 1 may be in any shape, and may be, for example, in a quadrangular shape or a circular shape.

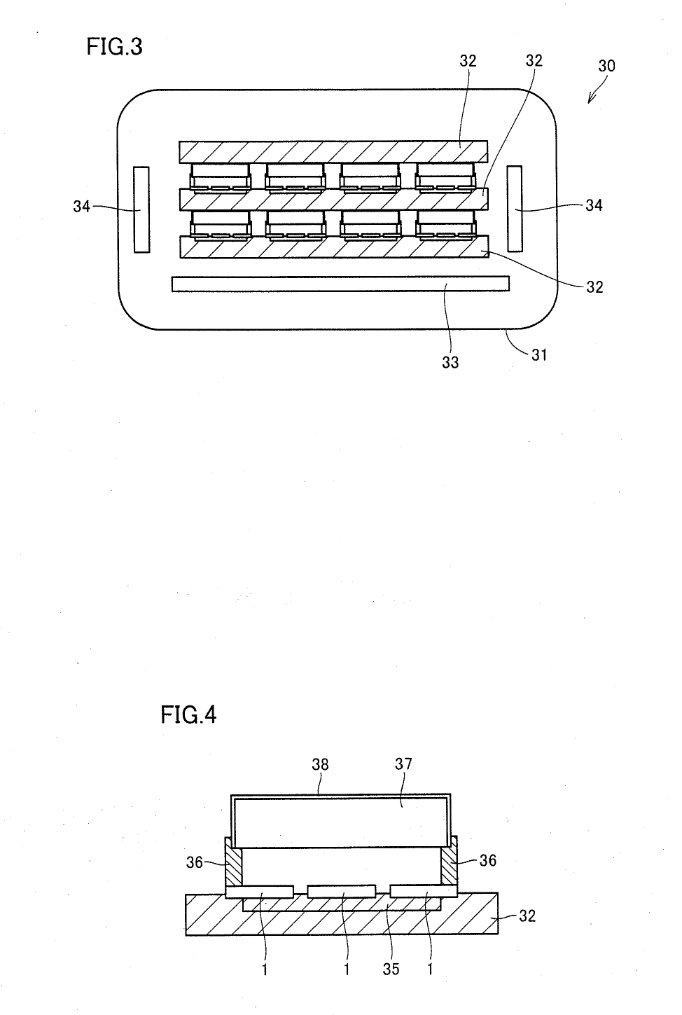

Next, as shown in FIG. 2, a step (S20) of forming the base member is performed. Specifically, using a sublimation method, base member 20 (see FIG. 5) made of silicon carbide is formed adjacent to the backside surfaces of the plurality of SiC single-crystal substrates 1. This step (S20) will be described more in detail below with reference to FIG. 3-FIG. 5.

In step (S20), a treatment device shown in FIG. 3 is employed. Referring to FIG. 3, a heat treatment device 30, which is an exemplary treatment device, includes: a chamber 31; base circular plates 32 disposed in chamber 31 and stacked over one another; the plurality of sets of SiC single-crystal substrates 1 and SiC members 37 disposed face to face with one another between base circular plates 32; and a main heater 33 and auxiliary heaters 34 disposed to surround the lower portion and side portions of base circular plates 32. Each of base circular plates 32 may have a circular planar shape. Base circular plate 32 has an upper surface provided with a plurality of recesses each having a predetermined planar shape (for example, circular shape). In each of the recesses, a carbon circular plate 35 is disposed. As shown in FIG. 4, carbon circular plate 35 has an upper surface provided with recesses for positioning, so as to allow SiC single-crystal substrates 1 to be disposed therein. In the recesses, SiC single-crystal substrates 1 are disposed. It should be noted that in FIG. 4 and FIG. 5, SiC single-crystal substrates 1 disposed have portions running off carbon circular plate 35. Hence, in order to hold the portions of SiC single-crystal substrates 1, base circular plate 32 is provided with another recess formed at an outer circumferential portion relative to the recess for disposing carbon circular plate 35 therein.

Then, a cylindrical body 36 having a circular planar shape is disposed to cover the outer circumference of the plurality of SiC single-crystal substrates 1 arranged on carbon circular plate 35 with the predetermined spaces therebetween. The cylindrical body has an upper end having an inner circumference provided with a groove. A SiC member 37 is disposed to be fit in this groove. SiC member 37 has a front-side surface covered with a coating film 38. This coating film 38 is formed to prevent silicon carbide, which will be sublimated from SiC member 37 in a below-described sublimation step, from being dissipated to outside cylindrical body 36.

From this SiC member 37, base member 20 (see FIG. 5) is formed using the sublimation method to cover the front-side surface of SiC single-crystal substrate 1. Specifically, with chamber 31 being set to have a predetermined atmosphere inside, the entire device (particularly, SiC member 37) is heated using main heater 33 and auxiliary heaters 34. As a result, silicon carbide sublimated from SiC member 37 is deposited on SiC single-crystal substrate 1 placed opposite to SiC member 37, thereby obtaining base member 20 made of silicon carbide as shown in FIG. 5. In this way, as shown in FIG. 5, base member 20 connecting the plurality of SiC single-crystal substrates 1 is formed.

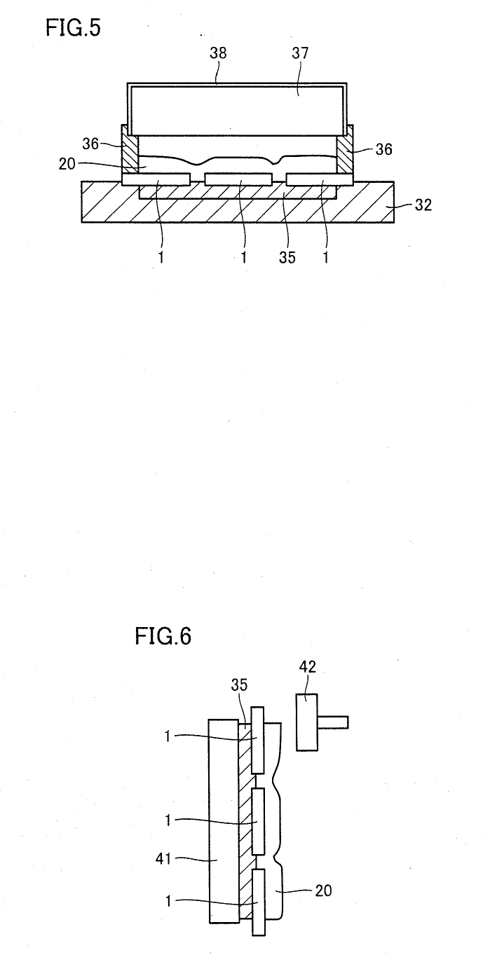

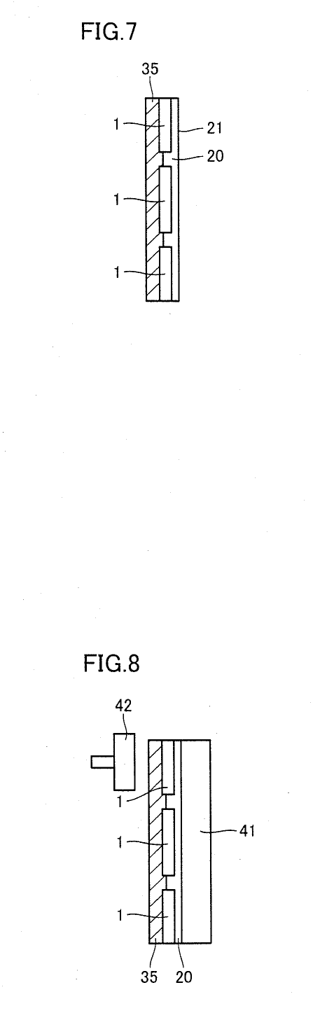

Next, as shown in FIG. 2, a post-process step (S30) is performed. Specifically, as shown in FIG. 6, the composite of SiC single-crystal substrates 1, base member 20, and carbon circular plate 35 is taken out of heat treatment device 30 (see FIG. 3), and then a surface of base member 20 (surface opposite to its surface facing SiC single-crystal substrate 1) is flattened. For example, as shown in FIG. 6, the composite is placed on a stage 41 with the surface of carbon circular plate 35 facing stage 41. Then, the surface of base member 20 is grinded using a grinding stone 42 to flatten it. As a result, surface 21 of the base member becomes flat as shown in FIG. 7.

Thereafter, as shown in FIG. 8, the composite is placed on stage 41 to bring the surface of base member 20 into contact with stage 41, and carbon circular plate 35 is grinded using grinding stone 42 to remove it. In grinding it, the surfaces of SiC single-crystal substrates 1 and portions of base member 20 located between adjacent SiC single-crystal substrates 1 are removed. Thereafter, stage 41 is removed from base member 20. As a result, as shown in FIG. 1, silicon carbide substrate 10 having the flat main surface can be obtained.

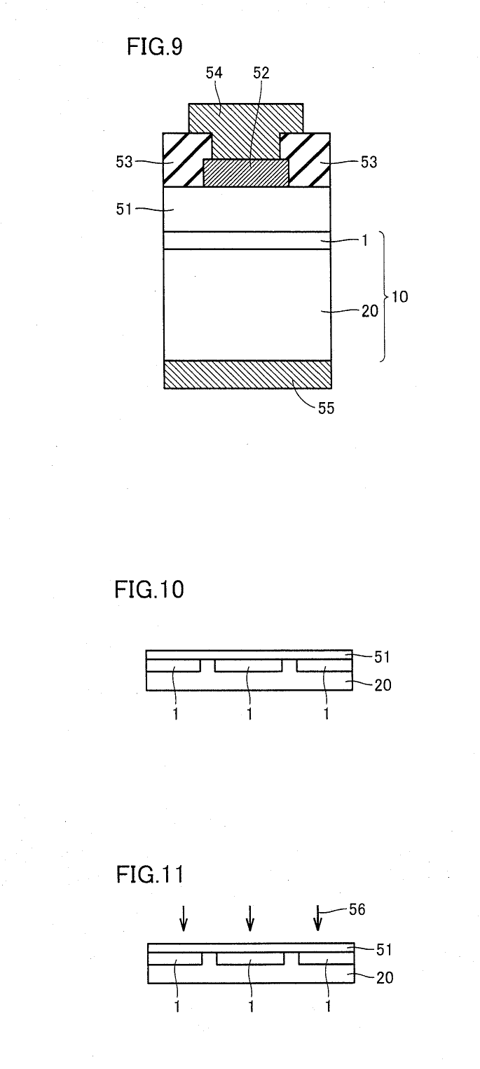

The following describes a semiconductor device according to the present invention with reference to FIG. 9.

Referring to FIG. 9, the semiconductor device according to the present invention is a Schottky barrier diode (SBD), and includes: silicon carbide substrate 10 including base member 20 and SiC single-crystal substrates 1; an epitaxial layer 51 formed on silicon carbide substrate 10 and made of silicon carbide; an Schottky electrode 52 formed on a main surface of epitaxial layer 51; and an ohmic electrode 55 formed on the backside surface of silicon carbide substrate 10 (surface opposite to the main surface on which epitaxial layer 51 is formed). Ohmic electrode 55 is formed to cover the entire backside surface of silicon carbide substrate 10. On the other hand, Schottky electrode 52 is formed to partially cover the front-side surface of epitaxial layer 51. For example, Schottky electrode 52 may have a circular planar shape.

Then, a protective film 53 is formed on the front-side surface of epitaxial layer 51. Protective film 53 is provided with an opening exposing a portion of the front-side surface of Schottky electrode 52. The opening can have any planar shape such as a circular shape or a quadrangular shape. A pad electrode 54 is formed to be connected to Schottky electrode 52 via the opening of protective film 53 and extend from within the opening to the upper surface of protective film 53.

Such a semiconductor device employs silicon carbide substrate 10 according to the present invention, thereby achieving improved conductivity in the vertical direction (thickness direction) of silicon carbide substrate 10. Accordingly, the on-resistance of the semiconductor device can be reduced.

The following describes a method for manufacturing the semiconductor device shown in FIG. 9 with reference to FIG. 10-FIG. 12.

First, silicon carbide substrate 10 according to the present invention is prepared by performing the method for manufacturing the silicon carbide substrate as shown in FIG. 2. Thereafter, as shown in FIG. 10, epitaxial layer 51 made of silicon carbide is formed on the main surface of silicon carbide substrate 10 (main surface from which SiC single-crystal substrates 1 are exposed).

Next, as shown in FIG. 11, a conductive impurity is implanted by means of ion implantation into epitaxial layer 51 in the direction indicated by arrows 56. As a condition for the ion implantation, any condition can be employed. It should be noted that the ion implantation step may not be performed in the case where a predetermined impurity can be contained in epitaxial layer 51 upon forming epitaxial layer 51 or the impurity concentration of epitaxial layer 51 does not need to be adjusted after forming epitaxial layer 51.

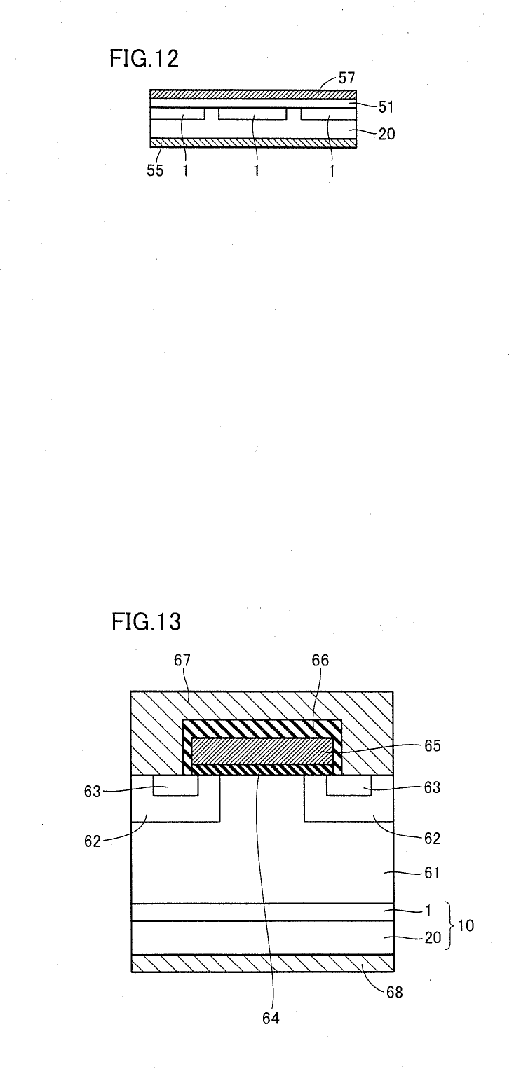

Thereafter, as shown in FIG. 12, an electrode forming step is performed. Specifically, a conductor layer 57 to be the Schottky electrode is formed on the front-side surface of epitaxial layer 51. Further, ohmic electrode 55 is formed on the backside surface of silicon carbide substrate 10. Thereafter, a portion of conductor layer 57 is removed using a lithography method or the like, thereby forming Schottky electrode 52. It should be noted that as the method for forming Schottky electrode 52, a so-called “lift-off method” may be employed. Specifically, for example, on epitaxial layer 51, a resist film is formed which has an opening pattern at a portion where Schottky electrode 52 is to be formed. Then, the conductor film to be the Schottky electrode is formed on the resist film and in the opening pattern, and thereafter the resist film and portions of the conductor film formed on the resist film are removed. As a result, the conductor film located in the above-described opening pattern is formed into the Schottky electrode.

Thereafter, the silicon carbide substrate having the above-described structure is divided into individual chips by means of dicing or the like, thereby obtaining the semiconductor device, which is a Schottky barrier diode, shown in FIG. 9.

The following describes another exemplary semiconductor device according to the present invention with reference to FIG. 13.

Referring to FIG. 13, this exemplary semiconductor according to the present invention is a vertical type DiMOSFET (Double Implanted MOSFET), and includes silicon carbide substrate 10, a breakdown voltage holding layer 61, p regions 62, n⁺ regions 63, a gate insulating film 64, a gate electrode 65, an insulating film 66, a source electrode 67, and a drain electrode 68. Specifically, for example, breakdown voltage holding layer 61 made of silicon carbide is formed on the main surface of silicon carbide substrate 10 including SiC single-crystal substrates 1 of n type conductivity and base member 20. Breakdown voltage holding layer 61 has a surface in which p regions 62 of p type conductivity are formed with a space therebetween. In each of p regions 62, an n⁺ region 63 is formed at the surface layer of p region 62.

Gate insulating film 64, which is formed of an oxide film, is formed to extend on n⁺ region 63 in one p region 62, p region 62, an exposed portion of breakdown voltage holding layer 61 between the two p regions 62, the other p region 62, and n⁺ region 63 in the other p region 62. On gate insulating film 64, gate electrode 65 is formed. Insulating film 66 is formed to cover the end faces and upper surface of gate electrode 65. Further, source electrode 67 is formed to be connected to portions of n⁺ regions 63 and p regions 62, and cover insulating film 66. Moreover, drain electrode 68 is formed on the backside surface of silicon carbide substrate 10, i.e., the surface opposite to its front-side surface on which breakdown voltage holding layer 61 is formed.

The semiconductor device shown in FIG. 13 employs silicon carbide substrate 10 according to the present invention. Further, in silicon carbide substrate 10, SiC single-crystal substrates 1 are disposed at the side on which breakdown voltage holding layer 61, which is the epitaxial layer, is formed, whereas base member 20 having a high impurity concentration (high conductivity) is disposed at the backside surface side. Hence, in the semiconductor device shown in FIG. 13, silicon carbide substrate 10 has improved conductivity in its thickness direction, with the result that the semiconductor device shown in FIG. 13 becomes a semiconductor device having reduced on-resistance.

The following briefly describes a method for manufacturing the semiconductor device shown in FIG. 13.

First, silicon carbide substrate 10 shown in FIG. 1 in the present invention is prepared using the method for manufacturing the silicon carbide substrate as shown in FIG. 2 and the like. It should be noted that as each of SiC single-crystal substrates 1 included in silicon carbide substrate 10, a substrate may be employed which has n type conductivity and has a substrate resistance of 0.02 Ωcm.

Next, a step of forming the epitaxial layer is performed. Specifically, breakdown voltage holding layer 61 is formed on the main surface of silicon carbide substrate 10 in which SiC single-crystal substrates 1 are formed. As breakdown voltage holding layer 61, a layer made of silicon carbide of n type conductivity is formed using an epitaxial growth method. Breakdown voltage holding layer 61 can have a thickness of, for example, 15 μm. Further, breakdown voltage holding layer 61 can have an n type conductive impurity concentration of, for example, 7.5×10¹⁵ cm⁻³.

It should be noted that a buffer layer may be formed between breakdown voltage holding layer 61 and silicon carbide substrate 10. As the buffer layer, for example, an epitaxial layer may be formed which is made of silicon carbide of n type conductivity and has a thickness of 0.5 μm, for example. The buffer layer has a conductive impurity at a concentration of, for example, 5×10¹⁷ cm⁻³.

Then, a step of forming the structure of the semiconductor element is performed. Specifically, first, an implantation step is performed. More specifically, an impurity of p type conductivity is implanted into breakdown voltage holding layer 61 using, as a mask, an oxide film formed through photolithography and etching, thereby forming p regions 62. Further, after removing the oxide film thus used, an oxide film having a new pattern is formed through photolithography and etching. Using this oxide film as a mask, a conductive impurity of n type conductivity is implanted into predetermined regions to form n⁺ regions 63.

After such an implantation step, an activation annealing process is performed. This activation annealing process can be performed under conditions that, for example, argon gas is employed as atmospheric gas, heating temperature is set at 1700° C., and heating time is set at 30 minutes.

Next, a gate insulating film forming step is performed. Specifically, gate insulating film 64 formed of oxide film is formed to cover breakdown voltage holding layer 61, p regions 62, and n⁺ regions 63. As a condition for forming gate insulating film 64, for example, dry oxidation (thermal oxidation) may be performed. The dry oxidation can be performed under conditions that the heating temperature is set at 1200° C. and the heating time is set at 30 minutes.

Thereafter, a nitrogen annealing step is performed. Specifically, an annealing process is performed in atmospheric gas of nitrogen monoxide (NO). Temperature conditions for this annealing process are, for example, as follows: the heating temperature is 1100° C. and the heating time is 120 minutes. As a result, nitrogen atoms are introduced into a vicinity of the interface between gate insulating film 64 and each of breakdown voltage holding layer 61, p regions 62, and n⁺ regions 63, which are disposed below gate insulating film 64. Further, after the annealing step using the atmospheric gas of nitrogen monoxide, additional annealing may be performed using argon (Ar) gas, which is an inert gas. Specifically, using the atmospheric gas of argon gas, the additional annealing may be performed under conditions that the heating temperature is set at 1300° C. and the heating time is set at 60 minutes.

Next, an electrode forming step is performed. Specifically, gate electrode 65 is formed on gate insulating film 64 using the lift-off method. Then, the insulating film is formed to cover the upper surface and side surfaces of gate electrode 65. Further, a resist film having a pattern is formed on insulating film 66, using a photolithography method. Using the resist film as a mask, portions of gate insulating film 64 and the insulating film above n⁺ regions 63 are removed by etching. As a result, insulating film 66 is formed to cover the upper surface and side surfaces of gate electrode 65, and portions of the upper surfaces of n⁺ region 63 and p region 62 are exposed.

Then, source electrode 67 is formed to be connected to the exposed portions of n⁺ region 63 and p region 62, using the lift-off method, for example. It should be noted that as source electrode 67, nickel (Ni) can be used, for example. It should be noted that on this occasion, heat treatment for alloying is preferably performed. Specifically, using atmospheric gas of argon (Ar) gas, which is an inert gas, the heat treatment (alloying treatment) is performed with the heating temperature being set at 950° C. and the heating time being set at 2 minutes. Thereafter, drain electrode 68 is formed on the backside surface of silicon carbide substrate 10. In this way, the semiconductor device shown in FIG. 13 can be obtained. Namely, the semiconductor device is fabricated by forming the epitaxial layer and the electrodes on the main surfaces of silicon carbide substrate 10.

It should be noted that in the above-described semiconductor device, it has been illustrated that the semiconductor device is fabricated by forming the epitaxial layer, which serves as an active layer, on SiC single-crystal substrates 1 each having its main face corresponding to the (0-33-8) plane. However, the crystal plane that can be adopted for the main face is not limited to this and any crystal plane suitable for the purpose of use and including the (0001) plane can be adopted for the main face.

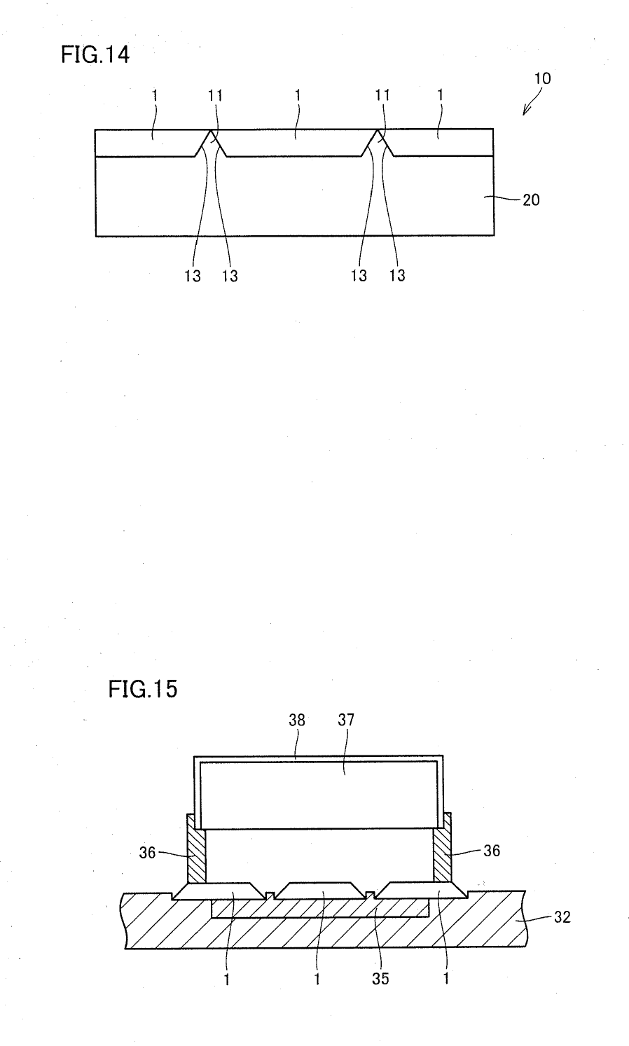

Referring to FIG. 14, the following describes a variation of the silicon carbide substrate of the first embodiment of the present invention.

Silicon carbide substrate 10 shown in FIG. 14 includes basically the same structure as that of silicon carbide substrate 10 shown in FIG. 1, but is different in its structure of end portions of SiC single-crystal substrates 1. Specifically, as shown in FIG. 14, each of the plurality of SiC single-crystal substrates 1 has end faces 13 inclined relative to the main surface of silicon carbide substrate 10. In this way, while attaining an effect similar to that in the silicon carbide substrate shown in FIG. 1, an area occupied by SiC single-crystal substrates 1 can become large in the main surface of silicon carbide substrate 10.

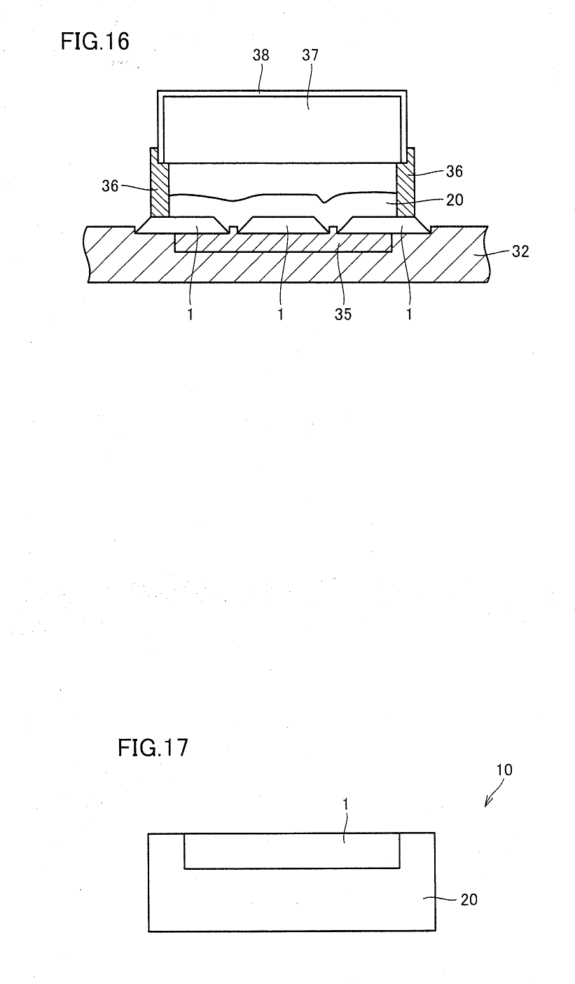

Referring to FIG. 15 and FIG. 16, the following describes a method for manufacturing the silicon carbide substrate shown in FIG. 14. It should be noted that FIG. 15 and FIG. 16 respectively correspond to FIG. 4 and FIG. 5.

The method for manufacturing the silicon carbide substrate shown in FIG. 14 is basically the same as the method for manufacturing silicon carbide substrate shown in FIG. 1, but is different in the shape of each SiC single-crystal substrate 1 prepared in step (S10) of preparing the single-crystal members. Specifically, SiC single-crystal substrate 1 prepared in step (S10) has the end faces inclined as shown in FIG. 15. Then, SiC single-crystal substrates 1 each having such inclined end faces is disposed in recesses of carbon circular plate 35 in the heat treatment device as shown in FIG. 15. In doing so, SiC single-crystal substrate 1 is disposed such that its main face having a relatively wide area is brought into contact with carbon circular plate 35. It should be noted that configurations of the other portions of the heat treatment device including the structure shown in each of FIG. 15 and FIG. 16 are the same as those of the heat treatment device shown in FIG. 4. Thereafter, by performing heat treatment in the heat treatment device in a manner similar to that in the method for manufacturing the silicon carbide substrate shown in FIG. 2, silicon carbide sublimated from SiC member 37 is deposited on SiC single-crystal substrates 1. As a result, as shown in FIG. 16, base member 20 made of silicon carbide is formed on SiC single-crystal substrates 1.

Thereafter, by performing post-process step (S30) shown in FIG. 2, the silicon carbide substrate shown in FIG. 14 can be obtained.

### Second Embodiment

Referring to FIG. 17, the following describes a silicon carbide substrate of a second embodiment of the present invention.

Referring to FIG. 17, silicon carbide substrate 10 according to the present invention has basically the same structure as that of silicon carbide substrate 10 shown in FIG. 1, but is different therefrom in that silicon carbide substrate 10 includes one SiC single-crystal substrate 1 whereas silicon carbide substrate 10 shown in FIG. 1 includes the plurality of SiC single-crystal substrates 1. Also in this case, an effect similar to that in silicon carbide substrate 10 shown in FIG. 1 can be obtained. Namely, the outer circumferential portion functions as a reinforcement member for maintaining mechanical strength of silicon carbide substrate 10, thus providing an effect of reducing warpage.

Further, the method for manufacturing silicon carbide substrate 10 shown in FIG. 17 is basically the same as the method for manufacturing silicon carbide substrate 10 shown in FIG. 1, but is different in that one SiC single-crystal substrate 1 is disposed on carbon circular plate 35 in the heat treatment device shown in each of FIG. 4 and FIG. 5 and then heat treatment is performed. The other steps are basically the same as those in the method for manufacturing the silicon carbide substrate as shown in FIG. 2.

### Third Embodiment

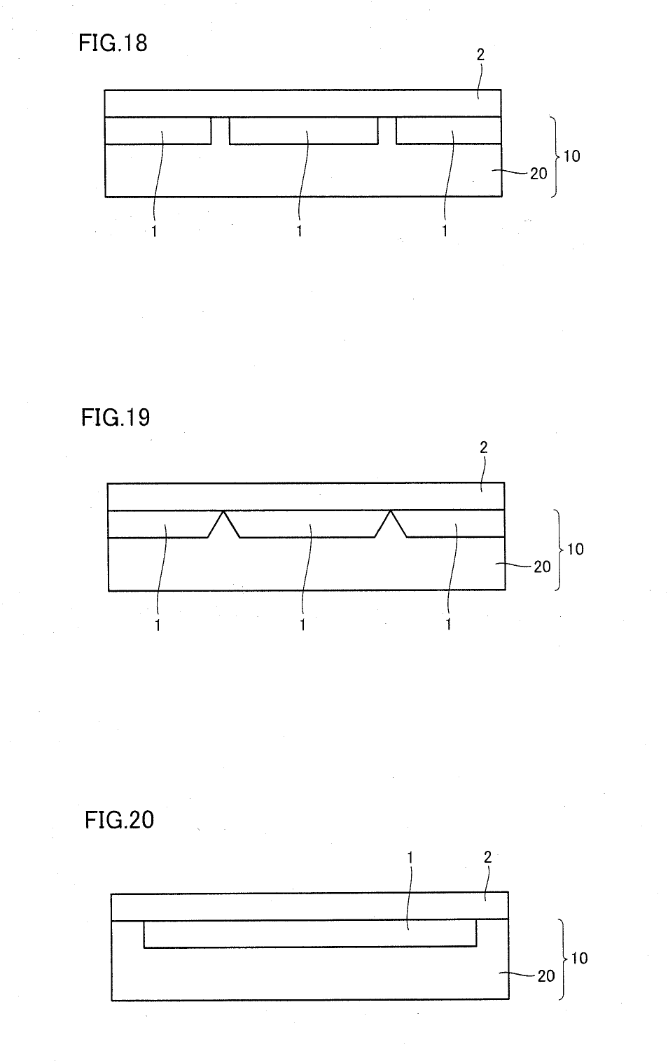

Referring to FIG. 18, an epitaxial layer provided substrate according to the present invention will be described.

Referring to FIG. 18, the epitaxial layer provided substrate according to the present invention has a structure such that epitaxial layer 2 made of silicon carbide is formed on the main surface of silicon carbide substrate 10 shown in FIG. 1 in the present invention. Using such an epitaxial layer provided substrate, a vertical type semiconductor device with reduced on-resistance can be manufactured readily.

Referring to FIG. 19 and FIG. 20, a variation of the epitaxial layer provided substrate shown in FIG. 18 in the present invention will be described.

The epitaxial layer provided substrate shown in FIG. 19 has a structure such that epitaxial layer 2 is formed on the main surface of silicon carbide substrate 10 shown in FIG. 14 in the present invention. The epitaxial layer provided substrate having such a structure also provides an effect similar to that provided by the epitaxial layer provided substrate shown in FIG. 18. Further, in the main surface of silicon carbide substrate 10 of the epitaxial layer provided substrate shown in FIG. 19, a ratio of the area in which each of SiC single-crystal substrates 1 is exposed is relatively higher than that in epitaxial layer provided substrate shown in FIG. 18. Accordingly, epitaxial layer 2 can be formed to have a large ratio of a region excellent in crystallinity (for example, low defect density).

The epitaxial layer provided substrate shown in FIG. 20 has basically the same structure as that of the epitaxial layer provided substrate shown in FIG. 18, but is different in that one SiC single-crystal substrate 1 is formed in the main surface of silicon carbide substrate 10. In this way, a ratio of the area occupied by SiC single-crystal substrate 1 in the main surface of silicon carbide substrate 10 can be larger than that in the case where the plurality of SiC single-crystal substrates 1 are disposed with a predetermined interval therebetween as shown in FIG. 18. This achieves more improved film quality of epitaxial layer 2.

It should be noted that the above-described sublimation method may be used as the method for manufacturing base member 20 of silicon carbide substrate 10, but other methods may be employed. For example, base member 20 made of silicon carbide may be formed using a CVD method. In this case, conditions usable for forming base member 20 using the CVD method are, for example, as follows: the flow rate of hydrogen serving as a carrier gas is set at 150 slm; substrate temperature (heating temperature of SiC single-crystal substrate 1) is set at 1650° C.; pressure in the atmosphere is set at 100 mbar; a ratio of the flow rate of SiH₄ gas to that of the above-described hydrogen gas is set at 0.6%; and a ratio of the flow rate of a HCl gas to that of the SiH₄ gas is set at 100%. In this case, base member 20 is grown at a rate of, for example, approximately 110 μm/h. By forming base member 20 using such a CVD method, precision of control is improved for the impurity concentration and thickness of base member 20. As a result, the thickness of base member 20 can be controlled to be a required minimum thickness in view of a grinding allowance in the post process. Hence, no excess grinding allowance for the grinding step needs to be secured. This can shorten time required for a processing step in the post process, such as the grinding step.

### Fourth Embodiment

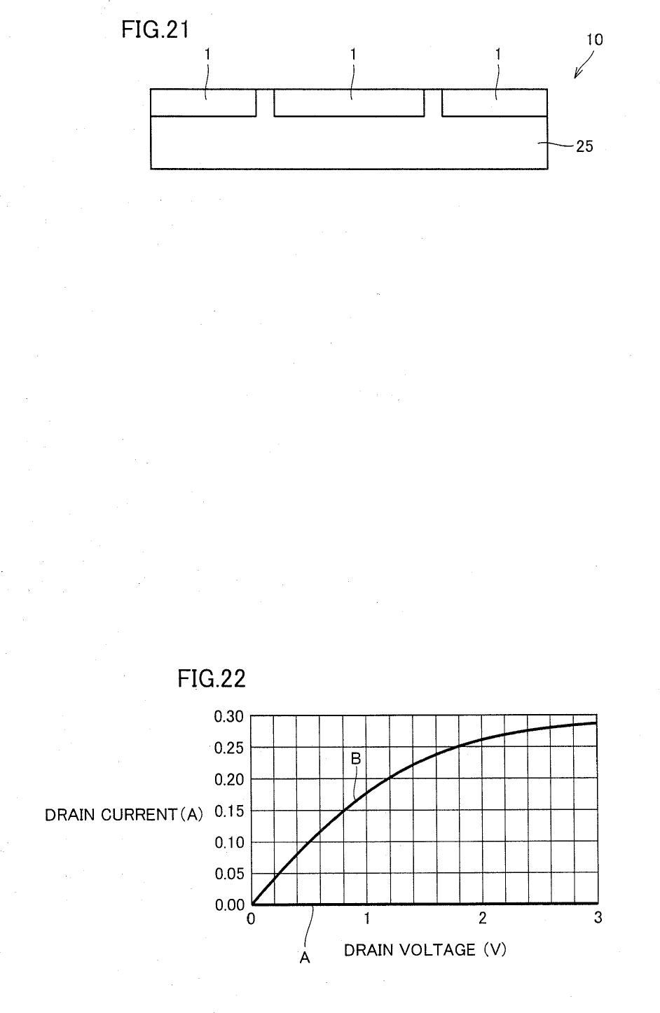

Referring to FIG. 21, the following describes a silicon carbide substrate of a fourth embodiment of the present invention.

Referring to FIG. 21, silicon carbide substrate 10 according to the present invention has basically the same structure as that of silicon carbide substrate 10 shown in FIG. 1, but is different in the configuration of the base member. Specifically, while silicon carbide substrate 10 shown in FIG. 1 employs base member 20 made of silicon carbide and formed by the sublimation method, silicon carbide substrate 10 shown in FIG. 21 employs a base member 25 formed of a sintered compact of silicon carbide. Base member 25 thus constituted by the sintered compact allows for further reduced manufacturing cost of silicon carbide substrate 10.

Here, as a step of forming base member 25 by means of sintering, the following step can be employed, for example. Namely, first, source materials to constitute base member 25 are prepared. The source materials to be prepared include, for example, SiC powders and silicon (Si) powders both having particle diameters in a micron order, and carbon powders having particle diameters in sub micron order. Further, for example, the mixture of the source powders are disposed on SiC single-crystal substrates 1 arranged as shown in FIG. 4, and is press-molded to prepare a molded member including the mixture of the powders and SiC single-crystal substrates 1. Then, in the molded member, Si powders are disposed on the main surface constituted only by the powders, and all of them are heated up to 1500° C. As a result, the Si powders are melted and the molded member is impregnated with the melted Si, which then reacts with the carbon powders in the molded member to become SiC. Then, the molded member is cooled and thereafter grinded by a grinding stone or the like, thereby obtaining silicon carbide substrate 10 shown in FIG. 21.

It should be noted that in silicon carbide substrate 10 shown in FIG. 21, each of SiC single-crystal substrates 1 may be configured in the same way as SiC single-crystal substrate 1 of silicon carbide substrate 10 shown in FIG. 14 or FIG. 17. Further, base member 25 constituted by the sintered compact may be applied to silicon carbide substrate 10 of the epitaxial layer provided substrate shown in FIG. 18-FIG. 20.

### EXAMPLE 1

The following experiment was performed to confirm the effect of the present invention.

(Fabrication of Sample)

Preparation of SiC Single-Crystal Substrate:

First, tile substrates each having a thickness of 100 μm were fabricated by slicing a 2-inch silicon carbide single-crystal ingot grown by the sublimation method. The silicon carbide single-crystal ingot had an impurity concentration of 9×10¹⁸ cm⁻³. It should be noted that each of the tile substrates had a main surface with a plane orientation corresponding to the (0001) plane.

Here, it has been reported that when the impurity concentration thereof is 9×10¹⁸ cm⁻³ or greater, defects at a surface of each tile substrate is propagated to come into the entire SiC single-crystal as described in Noboru Ohtani et. al, “Investigation of heavily nitrogen-doped n⁺ 4H-SiC crystals grown by physical vapor transport”, Journal of Crystal Growth 311 (2009), p. 1475-1481. In view of this, the ingot needs to have an impurity concentration not more than 9×10¹⁸ cm⁻³.

Next, the tile substrate was shaped into a SiC single-crystal substrate of 22 mm□ (quadrangular shape of 22 mm in length×22 mm in width). From this SiC single-crystal substrate, 49 devices of 2.7 mm□ can be obtained (devices each having a quadrangular planar shape with 2.7 mm in length×2.7 mm in the width).

Preparation of Carbon Circular Plate:

Next, for treatment in the heat treatment device shown in FIG. 3-FIG. 5, a carbon circular plate (see FIG. 4) having a plurality of counterbores (recesses) was prepared. Specifically, each of the counterbores had a planar shape of 22 mm□, had a positive tolerance, and had a depth of 30 μm. In the carbon circular plate, the counterbores (recesses) were provided at an interval of 100 μm. The carbon circular plate had a diameter of 155 mm, and had a thickness of 2 mm.

A reason of setting the thickness thereof at 2 mm, which is relatively thin, was to minimize stress imposed on the SiC single-crystal substrate by absorbing stress, caused by crystal growth, in the carbon circular plate. The plurality of counterbores each having a depth of 30 μm were formed for alignment of the SiC single-crystal substrates.

Preparation of Base Circular Plate:

A base circular plate was prepared which was a large carbon circular plate having a diameter of 650 mm and a thickness of 20 mm. The base circular plate was provided with 14 counterbores each having a diameter φ of 155 mm, a positive tolerance, and a depth of 1.9 mm.

Then, the carbon circular plate was placed in each of the counterbores of the base circular plate. With the carbon circular plate thus placed in the base circular plate, counterbores each having a depth of 30 μm were formed in the surface of the base circular plate so as to be continuous to the counterbores provided in the carbon circular plate and having a depth of 30 μm.

Arrangement of SiC Single-Crystal Substrates:

After placing the carbon circular plates in the base circular plate as described above, SiC single-crystal substrates were placed in the counterbores formed in the carbon circular plates and having a depth of 30 μm. Then, a cylindrical body, which was a cylinder having an inner diameter of 151 mm and a height of 5 mm, was placed to be concentric with each carbon circular plate. The cylindrical body had a lower portion in contact with the outer circumferential portion of the carbon circular plate. Then, a SiC member was provided at the upper portion of the cylindrical body. The SiC member was a polycrystal circular pillar made of silicon carbide and coated with a carbon film serving as a coating film. The SiC member in the form of the polycrystal circular pillar of silicon carbide was fabricated by the sublimation method and had a size with a diameter of 152 mm and a thickness of 30 mm. On this occasion, the SiC member had one surface not coated with the carbon film, and the SiC member was disposed such that the surface not coated faced the inside of the cylindrical body (i.e., faced the SiC single-crystal substrate). It should be noted that as described above, the coating for the carbon film is to suppress sublimation of silicon carbide from the SiC member.

A distance was approximately 5 mm between the surface of SiC member in the form of the polycrystal circular pillar and the surface of each SiC single-crystal substrate. The cylindrical body had an upper portion provided with an engagement portion (groove portion) for preventing displacement of the SiC member, and a flange serving as a spacer for preventing the 14 cylindrical bodies from being displaced from one another. This SiC member can be fabricated by a method such as the sublimation method, the CVD method, or sintering of SiC powder in an atmosphere having a high nitrogen concentration. 14 treatment sets of the above-described silicon carbide substrates were disposed on the base circular plate. Then, two such base circular plates were stacked over each other, and therefore 28 treatment sets were placed in the chamber in total.

Heat Treatment:

The treatment sets were thermally treated by the heat treatment device retained in the chamber, under the following conditions. Specifically, atmosphere in the chamber was set to be nitrogen atmosphere and have a pressure of 1 Torr. Further, the heating temperature was set at 2200° C., and the heat time was set at 30 minutes. As a result, base member 20 was grown which was made of silicon carbide and had a thickness of 600 μm and a high impurity concentration (see FIG. 5).

Post Process:

Next, composites each including the SiC single-crystal substrates incorporated by the base member having a high impurity concentration were taken out therefrom. Then, as shown in FIG. 6, the base member made of silicon carbide with a high impurity concentration was flattened by grinding, while simultaneously processing the outer circumference of each composite. As a result, the incorporated composite having a diameter φ of 6 inches was obtained as shown in FIG. 7. Next, as shown in FIG. 8, the carbon circular plate was also removed by grinding. Thereafter, the base member side of the incorporated composite, i.e., the side with the high impurity concentration, was attached to a grinder (stage), and then the SiC single-crystal substrate side thereof was polished. Finally, the SiC single-crystal substrate side was subjected to chemical mechanical polishing (CMP). In this way, the incorporated silicon carbide substrate having a diameter of 6 inches was obtained.

(Measurement and Result of Warpage in Silicon Carbide Substrate)

Warpage of the silicon carbide substrate was measured. In the measurement, a laser interferometer was used.

As a result, the warpage of the entire silicon carbide substrate having a diameter of 6 inches had a height of 10 μm or smaller. This is considered to be attained because boundary regions 11 (see FIG. 1), which were polycrystal portions at the boundaries between the SiC single-crystal substrates, suppressed propagation of basal plane dislocations to result in flatness maintained in the silicon carbide substrate.

(Fabrication of Epitaxial Layer Provided Substrate)

An epitaxial layer having a thickness of 15 μm and a carrier concentration of 7.5×10¹⁵ cm⁻³ was formed using a CVD device on the main surface of the incorporated silicon carbide substrate having a diameter of 6 inches (main surface from which the SiC single-crystal substrates were exposed). Conditions for epitaxial growth were as follows: substrate temperature was set at 1550° C., hydrogen flow rate was set at 150 slm, SiH₄ flow rate was set at 50 sccm, C₂H₆ flow rate was set at 50 sccm, 2 ppm nitrogen was set at 6 sccm, and growth time was set at 90 minutes.

(Fabrication of Schottky Barrier Diode)

Aluminum (Al) was provided by means of ion implantation to epitaxial layer formed as described above, and then activation annealing was performed to form a guard ring. Then, a film made of TiAlSi was formed on the backside surface (base member side) of the silicon carbide substrate by means of sputtering, and then annealing was performed at 900° C., thereby forming a backside surface ohmic electrode.

Meanwhile, Ti was deposited in vacuum on the entire front-side surface of the epitaxial layer and was then etched to form a Schottky electrode of 2.4 mm□ (quadrangular shape of 2.4 mm in length×2.4 mm in width). Then, Schottky annealing was performed with the heating temperature being at 500° C., and then a protective film (passivation film) made of SiO₂ was formed. Thereafter, a pad electrode connected to the Schottky electrode and made of Al/Si was formed, and then they were formed into chips by means of laser dicing, thereby forming Schottky barrier diodes. Then, each of the Schottky barrier diodes was provided in a frame for measurements.

(Measurements and Results for Schottky Barrier Diode)

As to On-Resistance:

The on-resistance of the Schottky barrier diode was measured. For the measurement, breakdown voltage also needed to be measured. For the measurement of breakdown voltage, a high breakdown voltage probe was used.

As a result, the Schottky diode had an on-resistance of 0.5 mΩcm². This value of the on-resistance was significantly smaller than that in a Schottky barrier diode formed using a conventional SiC single-crystal substrate. This is considered to be attained because the electric resistance value of the silicon carbide substrate according to the present invention was reduced to approximately 1/10 of the that of the conventional SiC single-crystal substrate.

As to Contact Resistance Associated with Ohmic Electrode:

Further, the silicon carbide substrate according to the present invention includes the high concentration impurity layer (base member), whereby the ohmic electrode can be formed on the backside surface at a low temperature. In order to confirm this, the backside surface of the silicon carbide substrate was back-grinded after fabricating the devices. Then, a damaged layer caused by the back-grinding was removed by polishing, and thereafter an electrode made of TiAlSi was formed on the polished surface. Thereafter, annealing was performed with a heating temperature being at 400° C. A contact resistance between the electrode thus formed and the backside surface of the silicon carbide substrate was measured. As a measurement method, a TLM method was used. As a result, the value of the contact resistance was 0.1 mΩcm², which is a sufficiently low contact resistance value.

### EXAMPLE 2

The CVD method was used instead of the sublimation method in the step of forming the base member in Example 1 described above. Specifically, the flow rate of hydrogen serving as a carrier gas was set at 150 slm, the substrate temperature (heating temperature for SiC single-crystal substrates 1) was set at 1650° C., the pressure of the atmosphere was set at 100 mbar, the flow rate ratio of SiH₄ gas to the above-described hydrogen gas was set at 0.6%, and the flow rate ratio of HCl gas to the SiH₄ gas was 100%. In this case, base member 20 had a growth rate of, for example, approximately 110 μm/h.

Also in the case of forming the base member using the CVD method, the silicon carbide substrate according to the present invention could be manufactured.

### EXAMPLE 3

The sintering method was used instead of the sublimation method in the step of forming the base member in Example 1 described above. Specifically, first, source materials to constitute the base member was prepared. The source materials to be prepared included, for example, SiC powders each having a particle diameter of approximately 10 μm and silicon (Si) powders each having a particle diameter of approximately 10 μm, and carbon powders each having a particle diameter of approximately 0.5 μm. Further, the mixture of the source powders were disposed on the tile substrates (SiC single-crystal substrates) arranged as with the case of Example 1 described above, and was press-molded to prepare molded members each including the mixture of the powders and the SiC single-crystal substrates. It should be noted that each molded member had a size with a diameter of 155 mm and a thickness of 1 mm. Further, in the molded member, Si powders were disposed on the main surface constituted only by the powders, and all of them were heated up to 1500° C. As a result, the Si powders were melted and the molded member was impregnated with the melted Si, which then reacted with the carbon powders in the molded member to become SiC. Then, the molded member was cooled and thereafter grinded by a grinding stone or the like, thereby obtaining a silicon carbide substrate having a shape similar to that in Example 1.

### EXAMPLE 4

(Fabrication of Silicon Carbide Substrate and Epitaxial Layer Provided Substrate)

A silicon carbide substrate was fabricated under conditions that: in the method for manufacturing the silicon carbide substrate described in Example 1, the main surface of each of the tile substrates was set to have a plane orientation corresponding to the (0-33-8) plane, and the other steps were set to be the same as the manufacturing steps in Example 1. Further, on the main surface of the silicon carbide substrate, an epitaxial layer was formed in the same manner as in Example 1, thereby fabricating an epitaxial layer provided substrate.

(Fabrication of Vertical Type DiMOSFET)

Using the epitaxial layer provided substrate, a semiconductor device was fabricated which had a structure basically the same as that of the vertical type DiMOSFET shown in FIG. 13. Specifically, phosphorus was provided by means of ion implantation to the epitaxial layer using a SiO₂ layer as a mask, thereby forming n⁺ regions (source portions) of the transistor. Next, p regions that were body portions having a p type conductivity were formed by implanting Al ions by means of the self-alignment using SiO₂. Then, the source portions and guard ring of p type adjacent to the above-described n⁺ regions and having a conductive impurity higher than that of the body portion of p type were formed by Al ion implantation. Thereafter, activation annealing was performed.

Next, the outermost surface layer of the epitaxial layer was removed by sacrifice oxidation to form a gate insulating film (gate oxide film) using thermal oxidation. A gate electrode made of polysilicon was formed thereon. Then, a source electrode made of TiAlSi was formed. Then, an interlayer insulating film made of SiO₂ and having a barrier layer made of SiN was formed on the source electrode, and an upper layer wire with a configuration of Al/Si is formed. Further, the entire upper surface thereof was covered with a protective film made of polyimide. Further, a backside surface electrode (drain electrode) was formed on the backside surface.

The substrate thus provided with the structure of transistor was divided by dicing, thereby obtaining chips of vertical type DiMOSFETs. Then, each of the chips was provided in a frame for measurements.

(Measurements and Results)

As to On-Resistance:

The on-resistance of the DiMOSFET was measured. As the measurement method, a method similar to the method for measuring the on-resistance in Example 1 was used.

As a result, the device had an on-resistance of 3 mΩcm².

As to Electric Characteristics:

Further, a relation between drain voltage and drain current in the above-described semiconductor device was measured. A result thereof is shown in FIG. 22. Referring to FIG. 22, the horizontal axis of the graph represents the drain voltage (V) whereas the vertical axis thereof represents the drain current (A). A graph A represents a relation between the drain voltage and the drain current when a gate voltage V_{G} is set at 0 V, whereas a graph B represents a relation between the drain voltage and the drain current when gate voltage V_{G} is set at 5V. It is understood from FIG. 22 that the semiconductor device according to the present invention attains a sufficient drain current value. Namely, the drain current value is approximately three times larger than that in the conventional semiconductor device (semiconductor device having its main surface having a plane orientation corresponding to the (0001) plane).

Further, a mobility of the semiconductor device described above was measured. A method for measuring the mobility was such that a lateral type MOSFET for evaluation was fabricated to measure an effective mobility. As a result, the mobility was greater by four times in the above-described semiconductor device formed using the silicon carbide substrate employing the tile substrates each having its main surface with a plane orientation corresponding to the (0-33-8) plane, than that in the conventional semiconductor device (semiconductor device in which the main surface had a plane orientation corresponding to the (0001) plane).

The following describes characteristic configurations in the present invention although some of them are repeatedly described in the foregoing embodiments or examples.

A silicon carbide substrate 10 according to the present invention is a silicon carbide substrate 10 having a main surface, and includes: a SiC single-crystal substrate 1 formed in at least a portion of the main surface and serving as a single-crystal member; and a base member 20, 25 disposed to surround SiC single-crystal substrate 1. Base member 20, 25 includes a boundary region 11 and a base region 12. Boundary region 11 is adjacent to SiC single-crystal substrate 1 in a direction along the main surface, and has a crystal grain boundary therein. Base region 12 is adjacent to SiC single-crystal substrate 1 in a direction perpendicular to the main surface, and has an impurity concentration higher than that of SiC single-crystal substrate 1. Further, base region 12 in base member 20 shown in FIG. 1 is a region formed of a single-crystal of silicon carbide.

In this way, because SiC single-crystal substrate 1 is disposed in the main surface of silicon carbide substrate 10, an epitaxial layer 2 (see FIG. 18-FIG. 20) made of silicon carbide of good film-quality can be readily formed on the main surface. On the other hand, when forming a vertical type semiconductor device such as those shown in, for example, FIG. 9 and FIG. 13 using silicon carbide substrate 10, silicon carbide substrate 10 needs to have a large conductivity in order to reduce the on-resistance of the vertical type semiconductor device. Hence, by disposing base region 12 having an impurity concentration higher than that of SiC single-crystal substrate 1, the conductivity of silicon carbide substrate 10 in its thickness direction (vertical direction) can become large (i.e., electric resistance value can be reduced in the thickness direction of silicon carbide substrate 10). Hence, the on-resistance of the semiconductor device (in particular, vertical type semiconductor device) employing silicon carbide substrate 10 can be reduced.

Further, basically, in order to form a high-quality epitaxial film on the main surface of silicon carbide substrate 10, SiC single-crystal substrate 1 having a low defect density (excellent crystallinity) is used. On the other hand, only the portion (boundary region 11) of base member 20, 25 is exposed in the main surface, and therefore may have a lower level of defect density or the like to be satisfied, than that in SiC single-crystal substrate 1. Hence, as base member 20, 25, there can be used a material doped with a conductive impurity at a high concentration (having an increased conductivity), without being limited by generation of defects or the like. Further, such base member 20, 25 can be used as a reinforcement member for maintaining mechanical strength of silicon carbide substrate 10. Further, an ohmic electrode can be readily formed on base member 20, 25 having the high impurity concentration.

Further, because required level for crystallinity in base member 20, 25 is not high as described above, a material (silicon carbide material) of low quality (inferior in crystallinity) can be used as base member 20, 25. Accordingly, manufacturing cost for silicon carbide substrate 10 can be reduced as compared with a case where the entire silicon carbide substrate 10 is constituted by a high-quality material such as SiC single-crystal substrate 1.

In silicon carbide substrate 10, boundary region 11 may have an impurity concentration higher than that of SiC single-crystal substrate 1. In this case, dislocations (for example, basal plane dislocations) propagating in SiC single-crystal substrate 1 can be absorbed in boundary region 11 more effectively. This suppresses silicon carbide substrate 10 from being warped due to the dislocations propagating throughout silicon carbide substrate 10.

Silicon carbide substrate 10 may further includes a SiC single-crystal substrate 1, which is another single-crystal member formed in at least the portion of the main surface as shown in FIG. 1. SiC single-crystal substrate 1 and another SiC single-crystal substrate 1 may be disposed with boundary region 11 interposed therebetween. Base region 12 may include a portion adjacent to another SiC single-crystal substrate 1 in the direction perpendicular to the main surface (i.e., base region 12 may extend from below one SiC single-crystal substrate 1 to a location adjacent to another SiC single-crystal substrate 1 in the direction perpendicular to the main surface).

In this case, by combining the plurality of SiC single-crystal substrates 1, silicon carbide substrate 10 having a main surface with a large area can be obtained. Accordingly, a larger number of semiconductor devices can be formed on the main surface of silicon carbide substrate 10 by one treatment. As a result, the manufacturing cost for the semiconductor devices can be reduced.

In silicon carbide substrate 10 described above, the impurity concentration of SiC single-crystal substrate 1 may be not less than 1×10¹⁷ cm⁻³ and not more than 2×10¹⁹ cm⁻³. The impurity concentration of base region 12 may be not less than 2×10¹⁹ cm⁻³ and not more than 5×10²² cm⁻³.

In this case, a high-quality epitaxial layer 2 can be formed on the main surface of silicon carbide substrate 10, and the conductivity of silicon carbide substrate 10 in the vertical direction can be sufficiently increased. Here, the lower limit of the impurity concentration of SiC single-crystal substrate 1 is set at the above-described value due to the following reason. That is, with an impurity concentration below the value (1×10¹⁷ cm⁻³), it becomes difficult to sufficiently secure the conductivity in SiC single-crystal substrate 1.

On the other hand, the upper limit of the impurity concentration of SiC single-crystal substrate 1 is set at the above-described value due to the following reason. That is, with an impurity concentration exceeding the value (2×10¹⁹ cm⁻³), stacking faults are generated in SiC single-crystal substrate 1. On the surface of SiC single-crystal substrate 1 thus having the stacking faults generated, it is difficult to form a high-quality epitaxial layer 2.

Further, the lower limit of the impurity concentration of base region 12 is set at the above-described value due to the following reason. That is, when the impurity concentration is equal to or higher than the value (2×10¹⁹ cm⁻³), the conductivity in base region 12 can be sufficiently increased.

On the other hand, the upper limit of the impurity concentration of base region 12 is set at the above-described value due to the following reason. That is, with an impurity concentration exceeding the value (5×10²² cm⁻³), density of defects resulting from the doping of impurity becomes too high. Accordingly, crystallinity in base region 12 cannot be maintained sufficiently.

An epitaxial layer provided substrate according to the present invention includes silicon carbide substrate 10 described above, and an epitaxial layer 2 formed on the main surface of silicon carbide substrate 10 and made of silicon carbide as shown in FIG. 18-FIG. 20. Further, epitaxial layer 2 may have an impurity concentration lower than that of SiC single-crystal substrate 1. In this case, a high-quality semiconductor device can be manufactured readily using epitaxial layer 2 that thus utilizes silicon carbide having high crystallinity (small in defect).

In the epitaxial layer provided substrate, epitaxial layer 2 may have an impurity concentration not less than 1×10¹⁴ cm⁻³ and not more than 1×10¹⁷ cm⁻³. Such a numerical range is adopted due to the following reason. Specifically, in a semiconductor device manufactured using the epitaxial layer provided substrate, it is preferable to set the impurity concentration of epitaxial layer 2 to fall within the above-described numerical range in view of a breakdown voltage level required for epitaxial layer 2 (for example, not less than 100 V and not more than 100,000 V).

A semiconductor device according to the present invention is formed using silicon carbide substrate 10 described above. In this case, for example, when forming a vertical type semiconductor device as shown in FIG. 9 or FIG. 13, conductivity of silicon carbide substrate 10 in its thickness direction can be sufficiently secured, thereby attaining a semiconductor device with reduced on-resistance.

The semiconductor device is preferably a vertical type semiconductor device in which a current flows in the thickness direction of silicon carbide substrate 10 as shown in FIG. 9 or FIG. 13, for example. Namely, it is preferable that a backside surface electrode (ohmic electrode 55 in FIG. 9 or drain electrode 68 in FIG. 13) is formed on the backside surface of silicon carbide substrate 10 (surface opposite to the above-described main surface), and a front-side surface electrode (Schottky electrode 52 in FIG. 9 or source electrode 67 in FIG. 13) is formed on the main surface thereof. In this case, a semiconductor device can be attained in which electric resistance (on-resistance) is sufficiently reduced between the front-side surface electrode and the backside surface electrode.

In a method for manufacturing a silicon carbide substrate according to the present invention, a step (step (S10) in FIG. 2) of preparing a single-crystal member (SiC single-crystal substrate 1) made of silicon carbide and having a main face is first performed as shown in FIG. 2. Performed thereafter is a step (step (S20) in FIG. 2) of forming a base member 20, 25 made of silicon carbide having an impurity concentration higher than that of SiC single-crystal substrate 1 so as to cover the main face and an end face of SiC single-crystal substrate 1. The end face is connected to the main surface and extends in a direction crossing the main face. Performed next is a step (step (S30) of FIG. 2) of flattening at least a surface of SiC single-crystal substrate 1 by partially removing SiC single-crystal substrate 1 and base member 20, 25 from a side opposite to the main face of SiC single-crystal substrate 1.

In this way, silicon carbide substrate 10 according to the present invention can be manufactured readily. Further, for base member 20, 25, a material (silicon carbide) having a lower crystallinity (for example, higher defect density) than that of SiC single-crystal substrate 1 can be used. Hence, silicon carbide substrate 10 can be manufactured at a lower cost than that in the case where the entire silicon carbide substrate 10 is constituted by a high-quality silicon carbide single-crystal such as SiC single-crystal substrate 1. Further, when a plurality of SiC single-crystal substrates 1 are used, silicon carbide substrate 10 having a large area can be attained.

In the method for manufacturing the silicon carbide substrate, step (S10) of preparing the single-crystal member may include a step of preparing another single-crystal member (another SiC single-crystal substrate 1) made of silicon carbide and having a main face. In step (S20) of forming the base member, with SiC single-crystal substrate 1 and another SiC single-crystal substrate 1 being arranged as shown in FIG. 4, base member 20 may be formed to cover the main face and an end face of another SiC single-crystal substrate 1 as shown in FIG. 5. The end face of another SiC single-crystal substrate 1 is connected to the main face of another SiC single-crystal substrate 1 and extends in a direction crossing the main face of another SiC single-crystal substrate 1. The step of flattening the surface of SiC single-crystal substrate 1 may include a step of flattening a surface of another SiC single-crystal substrate 1 by partially removing another SiC single-crystal substrate 1 and base member 20, 25. In this case, a single-crystal substrate having a large area can be obtained using the plurality of SiC single-crystal substrate 1.

In the method for manufacturing the silicon carbide substrate, in step (S20) of forming the base member, one of a hydride vapor phase epitaxy (HVPE method) and a chemical vapor deposition (CVD) method may be used. In this case, the impurity concentration in base member 20 can be controlled with high precision.

In the method for manufacturing the silicon carbide substrate, in step (S20) of forming the base member, a sublimation method may be used. In this case, base member 20 can be formed at a relatively low cost, thus reducing a manufacturing cost for silicon carbide substrate 10.

In the method for manufacturing the silicon carbide substrate, in step (S20) of forming the base member, a sintering method may be used as described in the foregoing fourth embodiment. In this case, base member 25 can be formed at a relatively low cost, thus reducing a manufacturing cost for silicon carbide substrate 10.

A method for manufacturing an epitaxial layer provided substrate according to the present invention includes the steps of: preparing silicon carbide substrate 10 described above; and forming an epitaxial layer 2 made of silicon carbide on the main surface of silicon carbide substrate 10 (main surface from which the flattened surface of SiC single-crystal substrate 1 is exposed). In this case, the epitaxial layer provided substrate according to the present invention can be readily manufactured.

A method for manufacturing a semiconductor device according to the present invention includes the steps of: preparing silicon carbide substrate 10 according to the present invention; forming an epitaxial layer 2 made of silicon carbide on the main surface of silicon carbide substrate 10; and forming electrodes on epitaxial layer 2 and a backside surface of silicon carbide substrate 10 opposite to the main surface on which epitaxial layer 2 is formed. In this case, the semiconductor device according to the present invention (in particular, vertical type semiconductor device shown in FIG. 9 or FIG. 13) can be manufactured readily. Further, the side of the backside surface of silicon carbide substrate 10 (base member 20, 25 side) includes base region 12 having a relatively high impurity concentration. Hence, an ohmic electrode can be formed readily by forming an electrode in contact with base region 12.

The embodiments and examples disclosed herein are illustrative and non-restrictive in any respect. The scope of the present invention is defined by the terms of the claims, rather than the embodiments described above, and is intended to include any modifications within the scope and meaning equivalent to the terms of the claims.

### INDUSTRIAL APPLICABILITY

The present invention is applied particularly advantageously to a silicon carbide substrate used to form a vertical type device, an epitaxial layer provided substrate, a semiconductor device, and a method for manufacturing the silicon carbide substrate.

### REFERENCE SIGNS LIST

1: SiC single-crystal substrate; 2, 51: epitaxial layer; 10: silicon carbide substrate; 11: boundary region; 12: base region; 13: end face; 20, 25: base member; 21: surface of base member; 30: heat treatment device; 31: chamber; 32: base circular plate; 33: main heater; 34: auxiliary heater; 35: carbon circular plate; 36: cylindrical body; 37: SiC member; 38: coating film; 41: stage; 42: grinding stone; 52: Schottky electrode; 53: protective film; 54: pad electrode; 55: ohmic electrode; 56: arrow; 57: conductor layer; 61: breakdown voltage holding layer; 62: p region; 63: n⁺ region; 64: gate insulating film; 65: gate electrode; 66: insulating film; 67: source electrode; 68: drain electrode.

1. A silicon carbide substrate having a main surface, comprising:
a single-crystal member formed in at least a portion of said main surface; and
a base member disposed to surround said single-crystal member,
said base member including
a boundary region adjacent to said single-crystal member in a direction along said main surface and having a crystal grain boundary therein, and
a base region adjacent to said single-crystal member in a direction perpendicular to said main surface and having an impurity concentration higher than that of said single-crystal member.

2. The silicon carbide substrate according to claim 1, wherein said boundary region has an impurity concentration higher than that of said single-crystal member.

3. The silicon carbide substrate according to claim 1, further comprising another single-crystal member formed in at least the portion of said main surface, wherein:
said single-crystal member and said another single-crystal member are disposed with said boundary region interposed therebetween, and
said base region includes a portion adjacent to said another single-crystal member in the direction perpendicular to said main surface.

4. The silicon carbide substrate according to claim 1, wherein:
the impurity concentration of said single-crystal member is not less than 1×10¹⁷ cm⁻³ and not more than 2×10¹⁹ cm⁻³, and
the impurity concentration of said base region is not less than 2×10¹⁹ cm⁻³ and not more than 5×10²² cm⁻³.

5. An epitaxial layer provided substrate comprising:
the silicon carbide substrate recited in claim 1; and
an epitaxial layer formed on said main surface of said silicon carbide substrate and made of silicon carbide.

6. A semiconductor device using the silicon carbide substrate recited in claim 1.

7. A method for manufacturing a silicon carbide substrate, comprising the steps of:
preparing a single-crystal member made of silicon carbide and having a main face;
forming a base member made of silicon carbide having an impurity concentration higher than that of said single-crystal member so as to cover said main face and an end face of said single-crystal member, said end face being connected to said main face and extending in a direction crossing said main face; and
flattening at least a surface of said single-crystal member by partially removing said single-crystal member and said base member from a side opposite to said main face of said single-crystal member.

8. The method for manufacturing the silicon carbide substrate according to claim 7, wherein:
the step of preparing said single-crystal member includes the step of preparing another single-crystal member made of silicon carbide and having a main face,
in the step of forming said base member, with said single-crystal member and said another single-crystal member being arranged, said base member is formed to cover said main face and an end face of said another single-crystal member, said end face of said another single-crystal member being connected to said main face of said another single-crystal member and extending in a direction crossing said main face of said another single-crystal member, and
the step (S30) of flattening the surface of said single-crystal member includes the step of flattening a surface of said another single-crystal member by partially removing said another single-crystal member and said base member.

9. The method for manufacturing the silicon carbide substrate according to claim 7, wherein in the step of forming said base member, one of a hydride vapor phase epitaxy or a chemical vapor deposition method is used.

10. The method for manufacturing the silicon carbide substrate according to claim 7, wherein in the step of forming said base member, a sublimation method is used.

11. The method for manufacturing the silicon carbide substrate according to claim 7, wherein in the step of forming said base member, a sintering method is used.
